(19) United States
(12) Patent Application Publication
(10) Pub. No.: US 2013/0234235 A1
(43) Pub. Date: Sep. 12, 2013

(54) METHOD FOR MANUFACTURING SEMICONDUCTOR MEMORY DEVICE AND SEMICONDUCTOR MEMORY DEVICE

(71) Applicant: KABUSHIKI KAISHA TOSHIBA, Tokyo (JP)

(72) Inventors: Toru MATSUDA, Mie-ken (JP); Tadashi Iguchi, Mie-ken (JP); Katsunori Yahashi, Mie-ken (JP)

(73) Assignee: Kabushiki Kaisha Toshiba, Tokyo (JP)

(21) Appl. No.: 13/788,295

(22) Filed: Mar. 7, 2013

(30) Foreign Application Priority Data
Mar. 7, 2012 (JP) 2012-050485
Mar. 6, 2013 (JP) 2013-044581

(51) Int. Cl. H01L 29/66; H01L 29/792

(52) U.S. Cl. CPC H01L 29/66833; H01L 29/7926
USPC 257/324; 438/268

(57) ABSTRACT

In one embodiment, a manufacturing method of a semiconductor memory device is disclosed. The method can include forming a stacked body on a substrate. The stacked body includes first silicon films containing impurities and having a concentration difference of the impurities provided among different layers, and non-doped second silicon films each provided between the first silicon films. The method can include forming a hole in the stacked body. The method can include removing the second silicon films by etching through the hole and forming an inter-electrode space between the first silicon films. The method can include forming a memory film including a charge storage film on a side wall of the hole and also forming at least a part of the memory film in the inter-electrode space.

### CROSS-REFERENCE TO RELATED APPLICATIONS

This application is based upon and claims the benefit of priorities from the prior Japanese Patent Applications No. 2012-050485, filed on Mar. 7, 2012 and No. 2013-044581, filed on Mar. 6, 2013; the entire contents of which are incorporated herein by reference.

### FIELD

Embodiments described herein relate generally to a method for manufacturing semiconductor memory device and a semiconductor memory device.

### BACKGROUND

A three-dimensionally structured memory device is proposed in which a memory hole is formed in a stacked body where a plurality of electrode films functioning as a control gate in a memory cell and inter-electrode insulating films are alternately stacked, and in which a silicon body serving as a channel through a charge storage film is provided on a side wall of the memory hole.

In the three-dimensionally structured memory device described above, increase in the number of electrode film layers invites increase of an aspect ratio and tends to cause shape control of the memory hole to be difficult.

### BRIEF DESCRIPTION OF THE DRAWINGS

FIG. 1 is a schematic perspective view of a semiconductor memory device of an embodiment;

FIG. 2 shows an enlarged cross-sectional view of the relevant part of the semiconductor memory device of the embodiment;

FIG. 3A to FIG. 6B are schematic view showing a method for manufacturing the semiconductor memory device according to a first embodiment;

FIG. 7A to FIG. 8 are schematic cross-sectional views showing a method for manufacturing a semiconductor memory device according to a second embodiment;

FIG. 9 is a schematic cross-sectional view showing a method for manufacturing a semiconductor memory device according to a third embodiment; and

FIG. 10A to FIG. 15 are schematic cross-sectional views showing a method for manufacturing a semiconductor memory device according to a fourth embodiment.

### DETAILED DESCRIPTION

In one embodiment, a manufacturing method of a semiconductor memory device is disclosed. The method can include forming a stacked body on a substrate. The stacked body includes a plurality of first silicon films containing impurities and having a concentration difference of the impurities provided among different layers, and a plurality of non-doped second silicon films each provided between the first silicon films. The method can include forming a hole in the stacked body. The method can include removing the second silicon films by etching through the hole and forming an inter-electrode space between the first silicon films. The method can include forming a memory film including a charge storage film on a side wall of the hole and also forming at least a part of the memory film in the inter-electrode space. In addition, the method can include forming a channel body inside the memory film within the hole.

In one embodiment, a manufacturing method of a semiconductor memory device is disclosed. The method can include forming a stacked body on a substrate. The stacked body includes a plurality of electrode films containing impurities and having a concentration difference of the impurities provided among different layers, and a plurality of insulating films each provided between the electrode films. The method can include forming a hole in the stacked body. The method can include etching a side wall of the electrode films exposed to the hole with an etchant. The method can include forming a memory film including a charge storage film on a side wall of the hole. In addition, the method can include forming a channel body inside the memory film within the hole. An etching rate of the electrode films to the etchant depends on a concentration of the impurities contained in the electrode films.

Various embodiments will be described hereinafter with reference to the accompanying drawings. In the drawings, the same components are marked with like reference numerals.

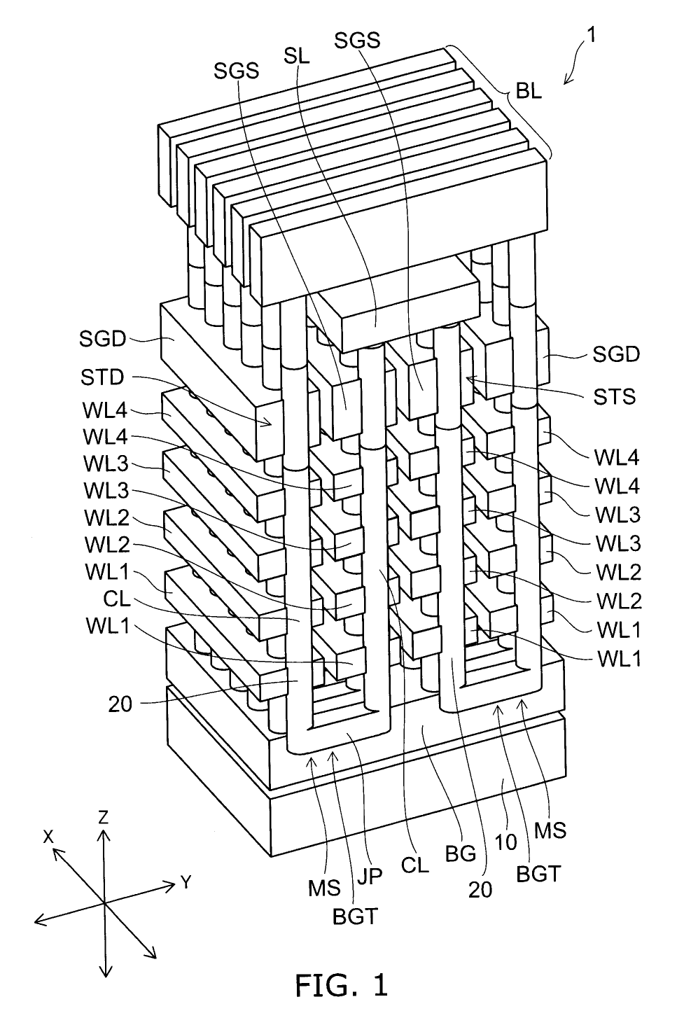

FIG. 1 is a schematic perspective view of a memory cell array 1 in a semiconductor memory device of the embodiment. In FIG. 1, in order for the figure to be made visible, an insulating portion is not illustrated.

In FIG. 1, an XYZ orthogonal coordinate system is introduced. Two directions which are parallel to the major surface of a substrate 10 and orthogonal to each other are defined as an X direction (first direction) and a Y direction (second direction), and a direction orthogonal to both of these X direction and Y direction is defined as a Z direction (third direction or stacking direction).

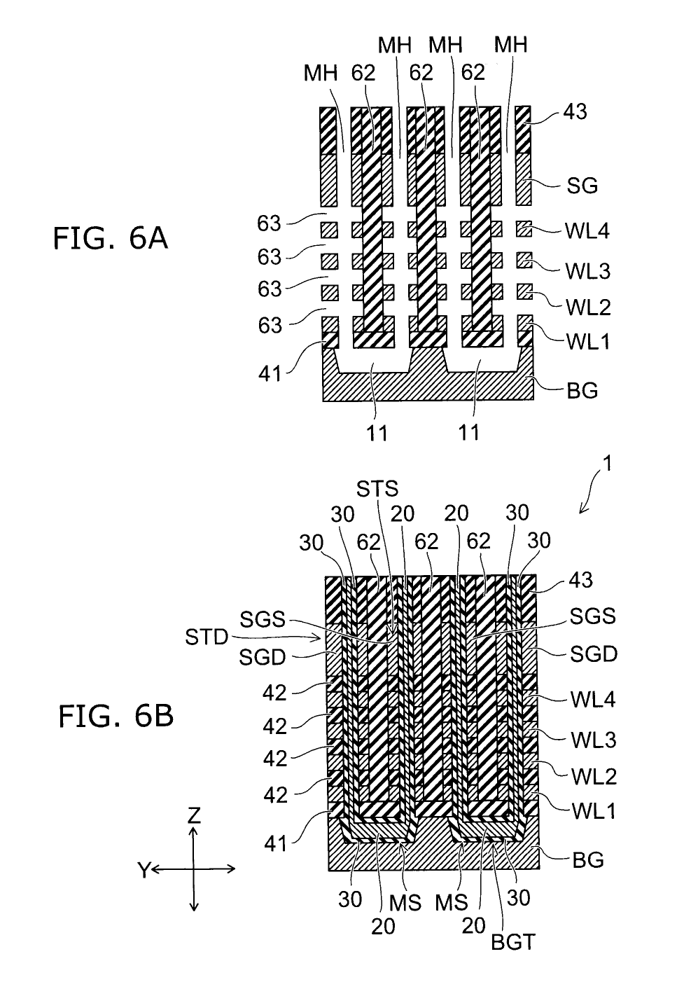

FIG. 6B is a schematic cross-sectional view of the memory cell array 1 and shows a cross section parallel to the YZ plane in FIG. 1. In FIG. 6B, the substrate 10 and a wiring or the like are omitted from the illustration.

The memory cell array 1 has a plurality of memory strings MS. One memory string MS is formed in a U-shape which has a pair of columnar parts CL extending in the Z direction and a junction part JP coupling the respective lower ends of the pair of columnar parts CL.

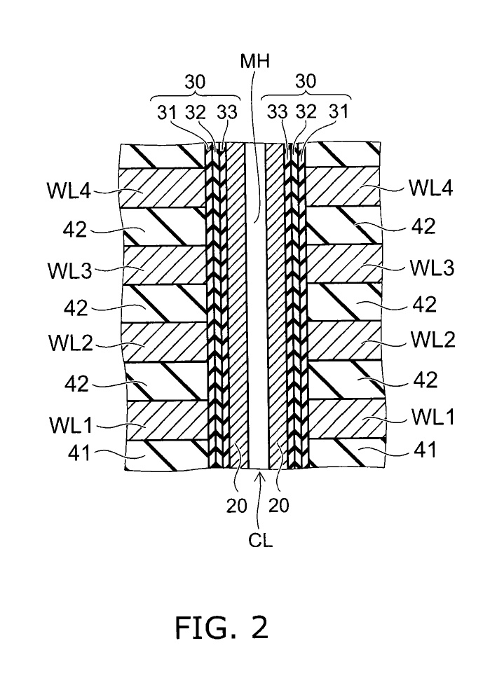

FIG. 2 shows an enlarged cross-sectional view of the columnar part CL in the memory string MS.

A back gate BG is provided on the substrate 10. The back gate BG is a conductive film, for example, a silicon film doped with impurities.

On the back gate BG, an insulating film 41 is provided as shown in FIG. 6B. On the insulating film 41, a plurality of electrode films WL1 to WL4 and a plurality of insulating films 42 are stacked alternately. While four layers of the electrode films WL1 to WL4 are illustrated in FIG. 1 and FIG. 6B, for example, the number of layers for the electrode films is optional.

The lowest layer of the electrode film WL1 is provided on the insulating film 41, the electrode film WL2 is provided on the electrode film WL1 via the insulating film 42, the electrode film WL3 is provided on the electrode film WL2 via the insulating film 42, and the electrode film WL 4 is provided on the electrode film WL3 via the insulating film 42.

Each of the electrode films WL1 to WL4 is a poly-silicon film (first silicon film) doped with boron, for example, as impurities and has a conductivity sufficient for functioning as a gate of a memory cell. Among the plurality of electrode films WL1 to WL4, as described below, impurity (boron) concentration is different.

The insulating films 41 and 42 are films mainly including silicon oxide, for example. Alternatively, films mainly including silicon nitride may be used as the insulating films 41 and 42.

a drain-side selection gate SGD is provided on one upper end of the pair of columnar parts CL in the U-shaped memory string MS and a source-side selection gate SGS is provided on the other upper end. The drain-side selection gate SGD and the source-side selection gate SGS are provided on the highest layer of the electrode film WL4 via the insulating film 42.

Each of the drain-side selection gate SGD and the source-side selection gate SGS is a poly-silicon film doped with boron, for example, as impurities the same as the electrode films WL1 to WL4, and has a conductivity sufficient for functioning as a gate electrode of a selection transistor. The thickness of the drain-side selection gate SGD and the thickness of the source-side selection gate SGS are thicker than each thickness of the electrode films WL1 to WL4.

The drain-side selection gate SGD and the source-side selection gate SGS are divided in the Y direction by an insulating isolation film 62 shown in FIG. 6B. The electrode films WL1 to WL4 stacked under the drain-side selection gate SGD and the electrode films WL1 to WL4 stacked under the source-side selection gate SGS are also divided in the Y direction by the insulating isolation film 62. The stacked body between the memory strings MS neighboring in the Y direction is also divided in the Y direction by the insulating isolation film 62.

On the source-side selection gate SGS, a source line SL shown in FIG. 1 is provided via an insulating film 43 shown in FIG. 6B. The source line SL is a metal film, for example.

On the drain-side selection gate SGD and the source line SL, bit lines BL of a plurality of metal wirings are provided via the insulating film 43. Each of the bit lines BL extends in the Y direction.

The memory string MS includes a channel body 20 provided in the U-shaped memory hole formed in the stacked body which includes the back gate BG, the plurality of electrode films WL1 to WL4, the insulating film 41, the plurality of inter-electrode insulating films 42, the drain-side selection gate SGD, and the source-side selection gate SGS.

The channel body 20 is provided via a memory film 30 in the U-shaped memory hole. The channel body 20 is a silicon film, for example. The memory film 30 is provided between the side wall of the memory hole MH and the channel body 20 as shown in FIG. 2.

While FIG. 2 shows a structure in which the channel body 20 is provided so as to leave a vacant part on the center axis side of the memory hole MH, the channel body 20 may fill the whole inside of the memory hole MH, or a structure in which insulating material fills the vacant part inside the channel body 20 may be used.

The memory film 30 has a block film 31, a charge storage film 32, and a tunnel film 33. Between each of the electrode films WL1 to WL 4 and the channel body 20, the block film 31, the charge storage film 32, and the tunnel film 33 are provided sequentially from the side of the electrode films WL1 to WL4. The block film 31 contacts each of the electrode films WL1 to WL4, the tunnel film 33 contacts the channel body 20, and the charge storage film 32 is provided between the block film 31 and the tunnel film 33.

The channel body 20 functions as a channel in the memory cell, the electrode films WL1 to WL4 function as control gates of the memory cells, and the charge storage film 32 functions a data storage layer accumulating electric charge injected from the channel body 20. That is, the memory cell having a structure in which the control gate surrounds the periphery of the channel is formed at a part where the channel body 20 and each of the electrode films WL1 to WL4 cross each other.

The semiconductor memory device of the embodiment is a non-volatile semiconductor memory device capable of performing data deletion and write-in freely in an electrical manner and retaining storage contents after a power source has been turned off.

The memory cell is a charge trap type memory cell, for example. The charge storage film 32 has many trap sites capturing electric charge and is configured with a silicon nitride film, for example.

The tunnel film 33 is a silicon oxide film, for example, and becomes a potential barrier when electric charge is injected into the charge storage film 32 from the channel body 20 or when electric charge accumulated in the charge storage film 32 diffuses into the channel body 20.

The block film 31 is a silicon oxide film, for example, and prevents electric charge accumulated in the charge storage film 32 from diffusing into the electrode films WL1 to WL4.

The drain-side selection gate SGD, the channel body 20, and the memory film 30 therebetween configure a drain-side selection transistor STD (shown in FIG. 1, FIG. 6B). The channel body 20 is connected to the bit line BL above the drain-side selection gate SGD.

The source-side selection gate SGS, the channel body 20, and the memory film 30 therebetween configure a source-side selection transistor STS (shown in FIG. 1, FIG. 6B). The channel body 20 is connected to the source line SL above the source-side selection gate SGS.

The back gate BG, the channel body 20 provided in the back gate BG and the memory film 30 configure a back gate transistor BGT (shown in FIG. 1, FIG. 6B).

Between the drain-side selection transistor STD and the back gate transistor BGT, a plurality of memory cells are provided having the respective electrode films WL1 to WL4 as control gates. Similarly, also between the back gate transistor BGT and the source-side selection transistor STS, a plurality of memory cells are provided having the respective electrode films WL1 to WL4 as control gates.

These plurality of memory cells, the drain-side selection transistor STD, the back gate transistor BGT, and the source-side selection transistor STS are connected in series through the channel body 20 and configure one U-shaped memory string MS. These plural memory strings MS are arranged in the X direction and the Y direction, and thereby the plurality of memory cells MC are provided three-dimensionally in the X direction, the Y direction, and the Z direction.

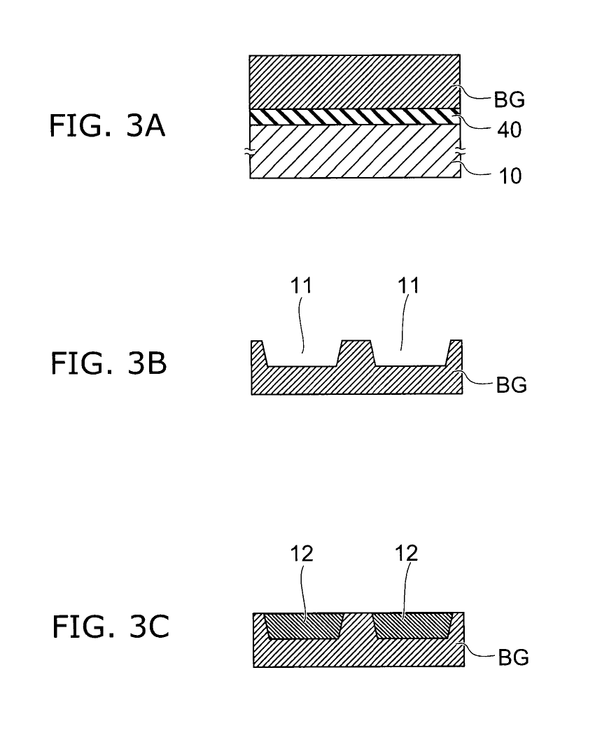

Next, a formation method of the memory array 1 according to the first embodiment will be explained with reference to FIG. 3A to FIG. 6B.

As shown in FIG. 3A, the back gate BG is formed on the substrate 10 via an insulating film (e.g., silicon oxide film) 40. The back gate BG is a poly-silicon film doped with boron (B). In FIG. 3B and the following drawings, the substrate 10 and the insulating film 40 will be omitted from the illustration.

On the back gate BG, a plurality of trenches 11 are formed as shown in FIG. 3B by etching using a mask which is not shown in the drawing.

In the trench 11, as shown in FIG. 3C, a sacrifice film 12 is embedded. The sacrifice film 12 is a non-doped silicon film. Here, the non-doped silicon film means that the silicon film is not intentionally doped with impurities which provide conductivity to the silicon film and substantially does not contain impurities except an element originating from source gas when the film is deposited.

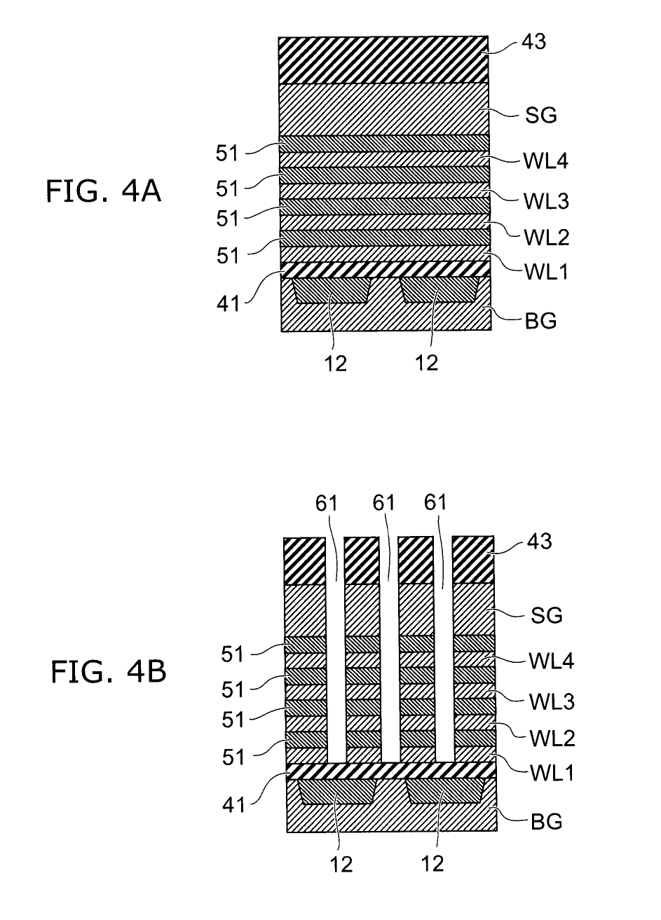

The upper face of a convex part in the back gate BG is exposed between the trench 11 and the trench 11. The upper face of the convex part in the back gate BG and the upper face of the sacrifice film 12 form flat faces flush with each other. On the flat faces, as shown in FIG. 4A, the insulating film 41 is formed. The insulating film 41 has a thickness sufficient to secure a certain breakdown voltage between the back gate BG and the lowest layer of the electrode film WL1.

The electrode film WL1 is formed on the insulating film 41 and a non-doped silicon film 51 is formed on the electrode film WL1, the electrode film WL2 is formed on the non-doped silicon film 51, a non-doped silicon film 51 is formed on the electrode film WL2, the electrode film WL3 is formed on the non-doped silicon film 51, a non-doped silicon film 51 is formed on the electrode film WL3, the electrode film WL4 is formed on the non-doped silicon film 51, and a non-doped silicon film 51 is formed on the electrode film WL4.

Further, on the highest layer of the non-doped silicon film 51, a selection gate SG which becomes the drain-side selection gate SGD or the source-side selection gate SGS is formed and the insulating film 43 is formed on the selection gate SG.

The back gate BG and the above stacked body on the back gate BG are formed by a CVD (Chemical Vapor Deposition) method, for example.

The number of layers for the electrode films WL1 to WL4 is optional and is not limited to four. According to the number of the layers for the electrode films WL1 to WL4, the number of layers for the non-doped silicon films 51 is changed.

The electrode films WL1 to WL4 are poly-silicon films (first silicon films) doped with boron (B), for example, as impurities. The non-doped silicon films 51 as the second silicon films are not intentionally doped with impurities which provide conductivity to the silicon films and substantially do not contain impurities except an element originating from source gas when the films are deposited.

The non-doped silicon layer 51 is replaced by the insulating layer 42 shown in FIG. 2 and FIG. 6B finally in a process to be described below. The non-doped silicon layer 51 has a thickness sufficient to secure a certain breakdown voltage between the electrode films WL1 to WL4.

In the embodiment, in the plurality of electrode films WL1 to WL4, boron concentration of the electrode film on the lower layer side is made lower than boron concentration of the electrode film on the higher layer side. For example, the electrode film on the lower layer side has a lower boron concentration. That is, the electrode layer WL3 has a boron concentration lower than the electrode film WL4, the electrode film WL2 has a boron concentration lower than the electrode film WL3, and the electrode film WL1 has a boron concentration lower than the electrode film WL2.

After the stacked body has been formed as shown in FIG. 4A, as shown in FIG. 4B, a plurality of trenches 61 which divide the stacked body and reach the insulating film 41 are formed by photolithography and etching. The trenches 61 divide the above stacked body in the Y direction of FIG. 1 and FIG. 6B on the sacrifice film 12 and on the portion between the neighboring sacrifice film 12 and sacrifice film 12.

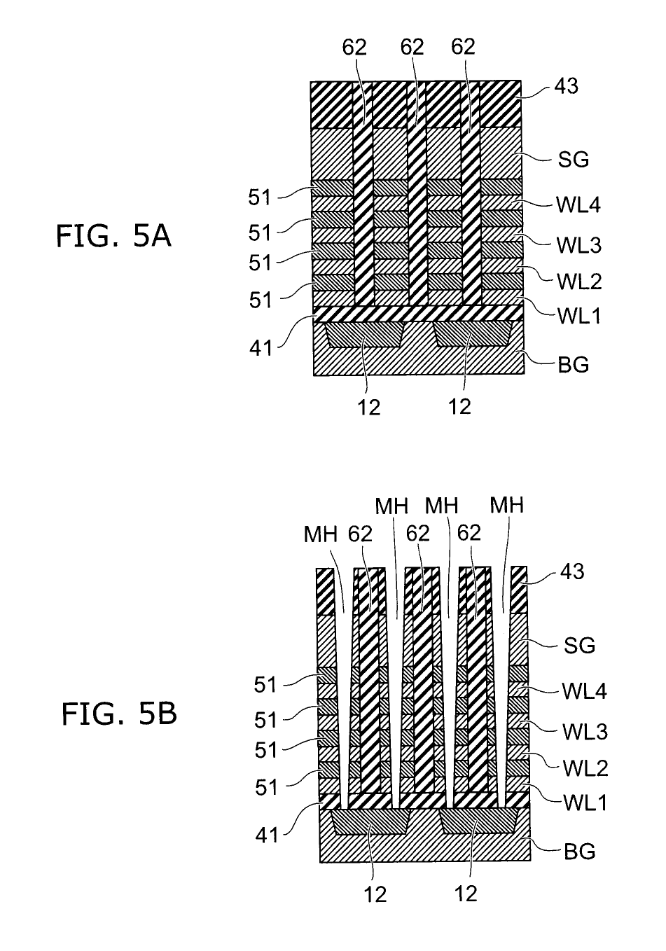

Within the trench 61, as shown in FIG. 5A, the insulating isolation film 62 is embedded. The insulating isolation film 62 is a silicon oxide film or a silicon nitride film, for example.

While the insulating isolation film 62 is deposited also on the insulating film 43, the insulating isolation film 62 on the insulating film 43 is removed and the insulating film 43 is exposed. The upper face of the insulating film 43 and the upper face of the insulating isolation film 62 are made flat flush with each other.

After the formation of the insulating isolation film 62, as shown in FIG. 5B, the plural memory holes MH are formed in the above stacked body. The memory hole MH is formed by an RIE (Reactive Ion Etching) method using a mask which is not shown in the drawing.

The whole stacked body between the insulating film 41 and the insulating film 43 is configured with silicon films, and therefore RIE condition setting and shape control of the memory hole MH are easy.

The bottom of the memory hole MH reaches the sacrifice film 12 and the sacrifice film 12 is exposed on the bottom of the memory hole MH. The pair of memory holes MH is formed on one sacrifice film 12 so as to sandwich the insulating isolation film 62. Further, on the side wall of the memory hole MH, the electrode films WL1 to WL4 and the non-doped silicon films 51 are exposed.

After the formation of the memory hole MH, the sacrifice film 12 and the non-doped silicon film 51 are removed by wet etching, for example. As etching solution at this time, alkaline chemical such as KOH (potassium hydrate) solution is used, for example. A state after this wet etching is shown in FIG. 6A.

The etching rate of the silicon film in the alkaline chemical depends on the concentration of the boron dopant in the silicon film. In particular, the etching rate is reduced abruptly when the boron concentration becomes not lower than 1×10²⁰ (cm⁻³) and becomes one several tenth of an etching rate for the boron concentration not higher than 1×10¹⁹ (cm⁻³).

According to the embodiment, the boron concentrations of the back gate BG, the electrode films WL1 to WL4, and the selection gate SG are 1×10²¹ (cm⁻³) to 2×10²¹ (cm⁻³). In the wet etching using the alkaline chemical, the etching selection ratio of the silicon film having a boron concentration 1×10²¹ (cm⁻³) to 2×10²¹ (cm⁻³) to the non-doped silicon film is 1/1,000 to 1/100.

Accordingly, by the above wet etching, the non-doped silicon film 51 and the sacrifice film 12 which is also a non-doped silicon film are removed through the memory hole MH. On the other hand, the back gate BG, the electrode films WL1 to WL4, and the selection gate SG are left.

By the removal of the sacrifice film 12, the trench 11 formed in the back gate BG by the previous process appears.

The pair of memory holes MH is connected to one of the trenches 11. That is, the respective bottoms of the pair of memory holes MH are connected to the one common trench 11, and the one U-shaped memory hole is formed.

By the removal of the non-doped silicon film 51, inter-electrode spaces 63 are formed between the electrode films WL1 to WL4. The inter-electrode space 63 is connected to the memory hole MH.

The electrode films WL1 to WL4 and the selection gate SG are supported by the insulating isolation film 62 and a state in which the electrode films WL1 to WL4 and the selection gate SG are stacked via the inter-electrode space 63 is retained.

FIG. 5B illustrates a shape in which the hole diameter of the memory hole MH becomes smaller toward the bottom. That is, the side wall of the memory hole MH has a tapered face not perpendicular but inclined to the substrate major surface. When the number of stacked layers for the electrode films is increased and the aspect ratio of the memory hole MH becomes higher, the memory hole MH tends to have a shape in which the diameter become smaller on the bottom side than on the top side.

A difference in the hole diameter of the memory hole MH in the depth direction may lead to a characteristic variation between the memory cell having the lower layer side electrode film as the control gate and the memory cell having the upper layer side electrode film as the control gate.

According to the embodiment, however, the shape of the memory hole MH can be adjusted after the RIE forming the memory hole MH.

The embodiment causes the lower layer side electrode film to have a lower boron concentration. As the boron concentration becomes lower, the etching rate by the alkaline chemical becomes higher. Accordingly, in the wet etching using the above alkaline chemical, the side wall of the lower layer side electrode film facing the memory hole MH is etched and recedes in the direction apart from the center axis of the memory hole

MH. That is, the hole diameter of the memory hole MH on the bottom side is increased and the taper shape of the memory hole MH on the bottom side is improved, and, as shown in FIG. 6A, the memory hole MH can be formed having an approximately uniform diameter from the top to the bottom.

For the electrode film having a lower boron concentration, etching tends to proceed also in the thickness direction. Accordingly, the electrode film having a lower boron concentration (higher layer side electrode film in the embodiment) is deposited to have a larger thickness and configured to have a desired film thickness after the above wet etching.

Alternatively, in the formation of the above stacked body, a film except a silicon film (e.g., silicon oxide film, silicon nitride film or the like) may be formed in the interface between each of the electrode films WL1 to WL4 and the non-doped silicon film 51, and it may be configured to prevent the electrode films WL1 to WL4 from being consumed in the thickness direction by the alkaline chemical.

A boron concentration not lower than 5×10²⁰ (cm⁻³) is sufficient for the electrode films WL1 to WL4 to function as the control gates of the memory cell. The embodiment causes the concentration difference to be generated among the electrode films WL1 to WL4 in a concentration region not lower than 1×10²¹ (cm⁻³) which is further higher than the electrically sufficient concentration. The boron concentrations of the back gate BG and the selection gate SG are also not lower than 1×10²¹ (cm⁻³).

Since the boron concentration difference is caused to be generated among the electrode films WL1 to WL4 in the concentration region considerably higher than the electrically sufficient boron concentration, the boron concentration difference among the electrode films WL1 to WL4 does not lead to a difference of the memory cell characteristics among the different layers.

After the above wet etching, as shown in FIG. 6B, the memory film 30 is formed on the side wall of the memory hole MH and also the insulating film 42 is formed in the inter-electrode space 63.

The memory film 30, as described with reference to FIG. 2, includes the block film 31, the charge storage film 32, and the tunnel film 33 which are stacked sequentially from the side wall side of the memory hole MH. At the same time when the memory film 30 is formed on the side wall of the memory hole MH, the insulating film 42 is formed also in the inter-electrode space 63. Accordingly, the insulating film 42 includes at least the block film 31 which is a part of the memory film 30.

According to the thickness (height) of the inter-electrode space 63 and the thickness in each of the films configuring the memory film 30, there is a case in which the inter-electrode space 63 is filled solely with the block film 31 or a case in which a stacked film including the block film 31 and the charge storage film 32 or a stacked film including the block film 31, the charge storage film 32, and the tunnel film 33 is embedded in the inter-electrode space 63 as the insulating film 42.

After that, inside the memory film 30 in the memory hole MH, the channel body 20 is formed. Further, after that, a contact which is not shown in the drawing, the source line SL and bit line BL which are shown in FIG. 1, and the like are formed.

According to the embodiment described above, even when it is difficult to perform processing of causing the memory hole MH to have a desired shape in the anisotropic etching (RIE) which causes the etching to proceed in the stacking direction of the stacked body, it is possible to adjust the shape of the memory hole MH in the wet etching which removes the non-doped silicon film, by changing the boron concentration of the electrode film among the different layers.

For example, as described above, when the diameter of the memory hole MH tends to become smaller on the bottom side than on the top side by RIE, the boron concentration of the electrode film is made lower on the lower layer side, and thereby the hole diameter of the memory hole MH can be adjusted uniformly from the top to the bottom and the memory cell characteristics is made uniform among the different layers.

Not limited to causing the respective boron concentrations of the plurality of electrode films WL1 to WL4 to be different from one another, by causing the boron concentration of the electrode film on the lower layer side to be relatively lower than the boron concentration of the electrode film on the upper layer side, it is possible to improve the taper shape of the memory hole MH as shown in FIG. 5B.

For example, the boron concentrations of the intermediate electrode films WL2 and WL3 may be made the same and the boron concentration of the lowest layer of the electrode film WL1 may be made lower than the boron concentration of the highest layer of the electrode film WL4. Alternatively, the boron concentrations of the electrode films WL1 and WL2 may be made the same and also the boron concentrations of the electrode films WL3 and WL4 may be made the same, and then the boron concentration of the electrode films WL1 and WL2 may be made lower than the boron concentration of the electrode films WL3 and WL4.

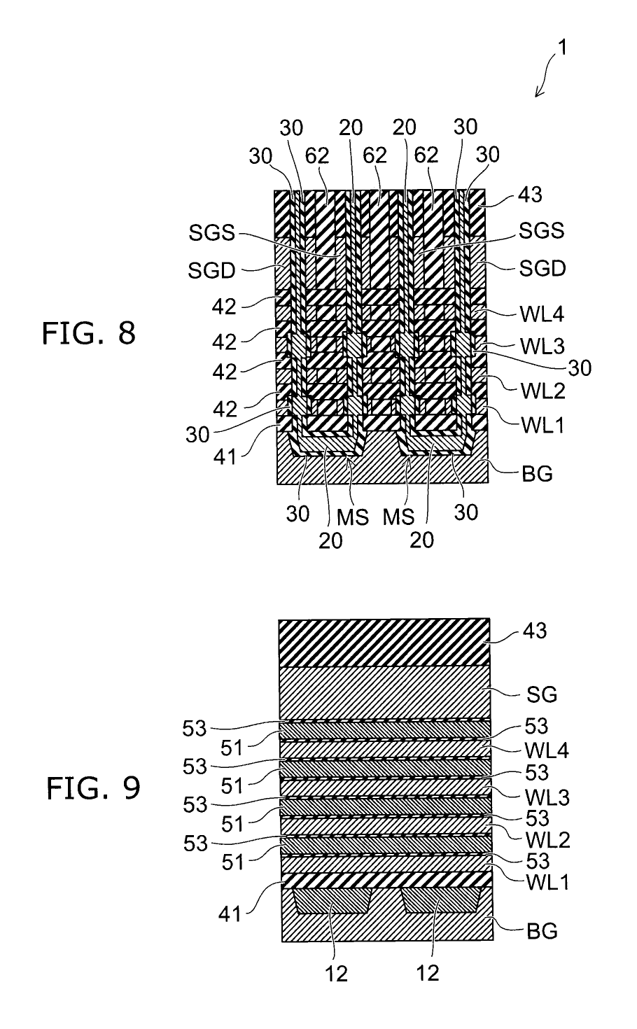

Further, not limited to controlling the hole diameter of the memory hole MH uniformly in the depth direction, similar to the second embodiment shown in FIG. 8, for example, it is also possible to perform shape control so as to alternately form a relatively small portion and a relatively large portion for the hole diameter in the depth direction.

For example, the boron concentrations of the electrode films WL1 and WL3 are made the same and also the boron concentration of the electrode films WL2 and WL4 are made the same, and then the boron concentration of the electrode films WL1 and WL3 are made lower than the boron concentration of the electrode films WL2 and WL4.

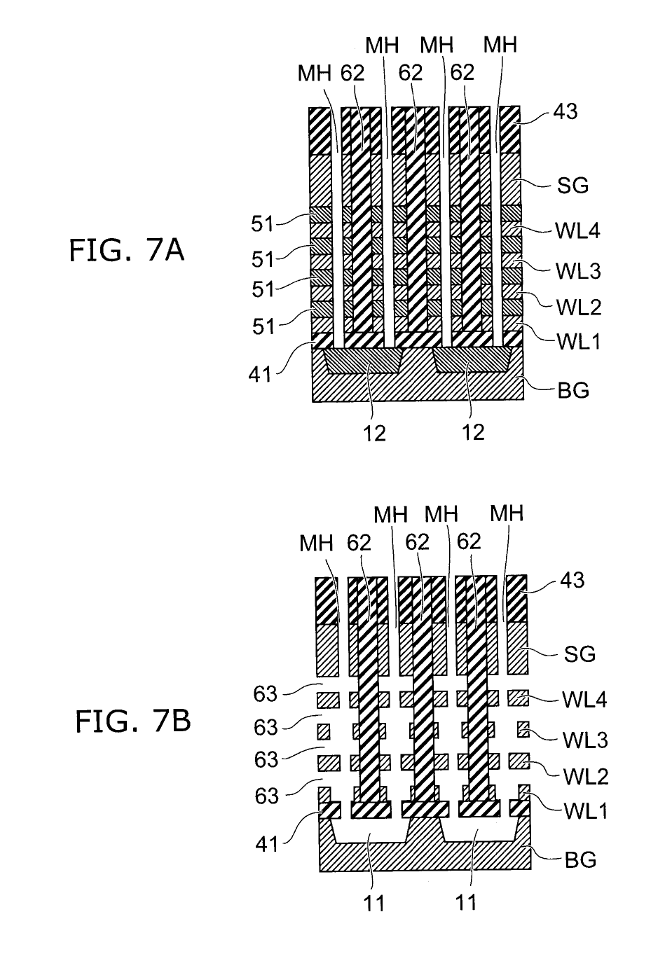

After the stacked body including such electrode films WL1 to WL4 has been formed the same as in the above embodiment, as shown in FIG. 7A, the memory hole MH is formed by an RIE method, for example. FIG. 7A illustrates a memory hole MH having a uniform hole diameter from the top to the bottom.

Then, after the formation of the memory hole MH, the sacrifice film 12 and the non-doped silicon film 51 are removed by the wet etching using the alkaline chemical.

Also in the embodiment, the boron concentrations of the back gate BG, the electrode films WL1 to WL4, and the selection gate SG are 1×10²¹ (cm⁻³) to 2×10²¹ (cm⁻³). Accordingly, by the above wet etching, the non-doped silicon film 51 and the sacrifice film 12 which is also a non-doped silicon film are removed through the memory hole MH as shown in FIG. 7B, and the back gate BG, the electrode films WL1 to WL4, and the selection gate SG are left.

According to the embodiment, the boron concentration of the electrode films WL1 and WL3 are made lower than the boron concentration of the electrode films WL2 and WL4. Accordingly, in the wet etching using the alkaline chemical, the side faces of the electrode films WL1 and WL3 facing the memory hole MH are etched more largely in the lateral direction than the side faces of the electrode films WL2 and WL4 facing the memory hole MH.

After the above wet etching, as in the above embodiment, as shown in FIG. 8, the memory film 30 is formed on the side wall of the memory hole MH and also the insulating film 42 is formed in the inter-electrode space 63. After that, the channel body 20 is formed inside the memory film 30 within the memory hole MH.

According to the embodiment, in the memory hole MH, it is possible to make the hole diameter of a portion surrounded by the electrode film WL1 and the hole diameter of a portion surrounded by the electrode film WL3 larger than the hole diameter of a portion surrounded by the electrode film WL2 and the hole diameter of a portion surrounded by the electrode film WL4. That is, a channel peripheral length around the center axis of the memory hole MH is longer in the memory cell of the bottom layer and the memory cell of the third layer from the bottom than in the memory cell of the second layer from the bottom and the memory cell of the highest layer.

That is, it is possible to arrange the memory cells having different characteristics alternately in the stacking direction of the memory cells. According to required specification, process tendency, and process variation, it is possible to optionally select which layer of the electrode films has a relatively lower born concentration or a relatively high boron concentration.

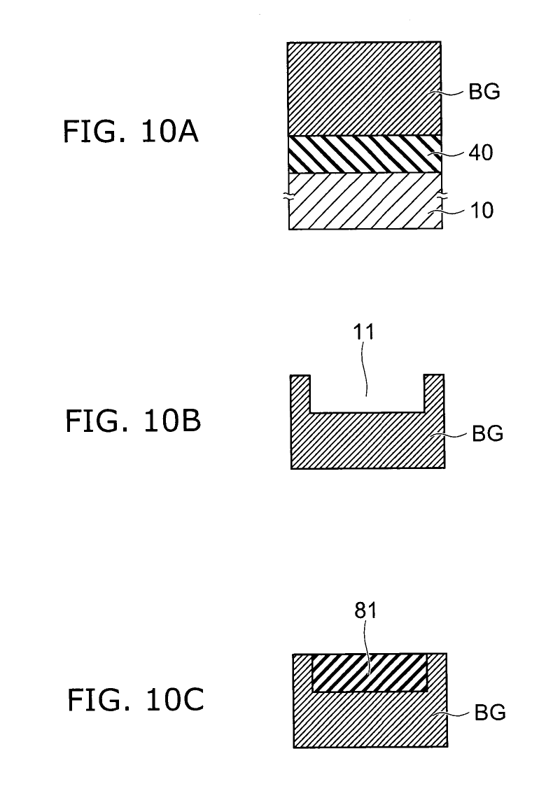

Next, a formation method of a memory cell array according to a fourth embodiment will be described with reference to FIG. 10A to FIG. 14.

As shown in FIG. 10A, the back gate BG is formed on the substrate 10 via an insulating film (e.g., silicon oxide film) 40. The back gate BG is a poly-silicon film doped with boron (B). In FIG. 10B and the following drawings, the substrate 10 and the insulating film 40 will be omitted from the illustration.

On the back gate BG, a plurality of trenches 11 are formed as shown in FIG. 10B by etching using a mask which is not shown in the drawing.

In the trench 11, as shown in FIG. 10C, a sacrifice film 81 is embedded. The sacrifice film 81 is a film made of a material different from the back gate BG, electrode films WL1 to WL4 and the insulating film 42, for example, a silicon nitride film.

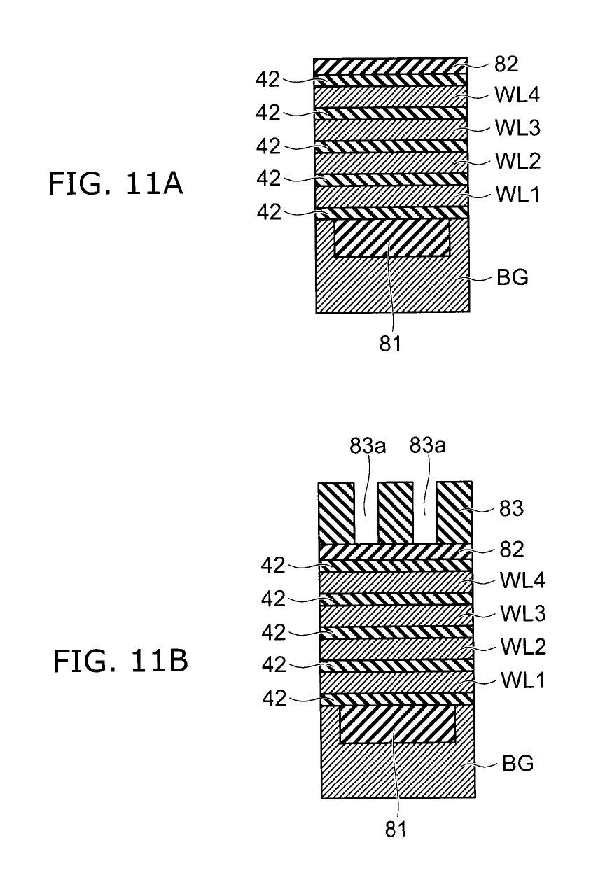

As shown in FIG. 11A, a stacked body having electrode films WL1 to WL4 alternately stacked is formed on an upper surface of sacrifice film 81 and the back gate BG. Layer number of WL1 to WL4 is arbitrary and is not limited to 4 layers.

The insulating film 42 is formed between the electrode film WL1 of the lowest layer and the back gate BG, between the electrode film WL1 of the lowest layer and the sacrifice layer, between the electrode films WL1 to WL4, and on the electrode film WL4 of the topmost layer. Furthermore, for example a silicon nitride film is formed as a mask 82 on the insulating layer 42 of the topmost layer.

The electrode films WL1 to WL4 are polycrystalline silicon film added with, for example, boron as an impurity. The insulating film 42 is, for example, a silicon oxide film.

Also in the embodiment, similar to the embodiment described above, an impurity (boron) concentration is different between the plurality of electrode films WL1 to WL4. For example, the boron concentration in the lower layer side electrode film is set lower than the boron concentration in the upper layer side electrode film. For example, the electrode film on the lower layer side has a lower boron concentration. As shown in FIG. 11B, a resist film 83 is formed on the mask film 82. A hole 83a is formed in the resist film 83 by exposure to light and development treatment.

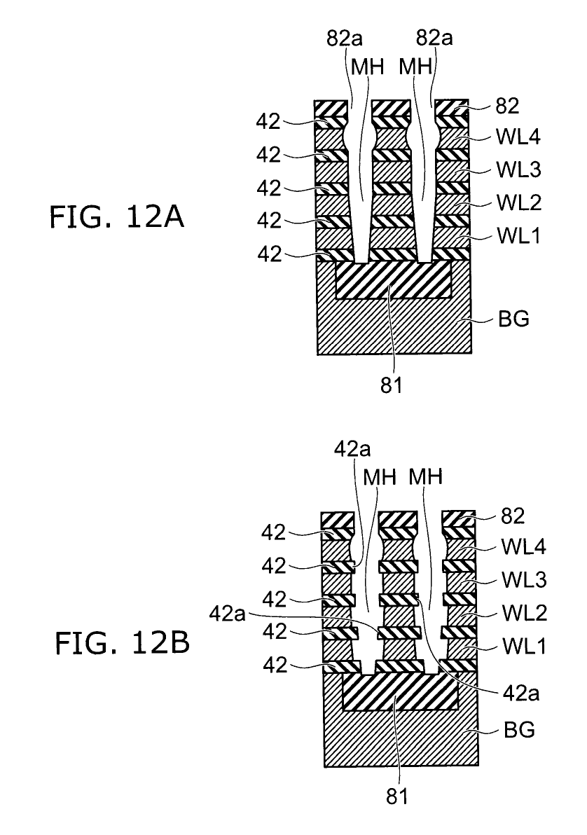

An opening 82a is formed in the mask film 82 as shown in FIG. 12A by, for example, RIE method used for causing the resist film 83 to be the mask, furthermore a memory hole MH is formed in the stacked body under the opening 82a. A bottom of the memory hole MH reaches the sacrifice film 81 and the sacrifice film 81 is exposed to the bottom of the memory hole MH.

It is difficult to process a hole extending perpendicularly to the substrate surface in the stacked body having heterogeneous materials of the electrode films WL1 to WL4 and the insulating film 42 alternately stacked by RIE method, and as shown in FIG. 12A, a side wall of the memory hole MH is likely to be in tapered shape slanted to the substrate surface or bowing shape. Particularly, with increasing stacked number of electrode films and increasing aspect ratio of the memory hole MH, it becomes difficult to control the shape of the hole formed by the RIE method.

When the side wall of the memory hole MH is in the tapered shape or the bowing shape, a concern is raised that the memory films formed on the side wall of the memory hole MH blocks the memory hole MH at a position with a small hole diameter, and the channel body becomes impossible to be formed.

The difference of the hole diameter in a depth direction of the memory hole MH may lead to variation of characteristics between a memory cell operating the electrode film on the lower layer side as the control gate and a memory cell operating the electrode film on the upper layer side.

Then, in the embodiment, the shape of the memory hole can be adjusted after the RIE forming the memory hole MH as described below.

After the RIE forming the memory hole MH, the side walls of the electrode films WL1 to WL4 exposed to inside of the memory hole MH are etched by a wet etching method. The etching liquid includes, for example, alkaline chemical such as KOH (potassium hydroxide) solution. FIG. 12 B shows the state after the etching.

As described previously, the etching rate of a silicon film to the alkaline chemical depends on the concentration of boron doped into the silicon film. Particularly, the etching rate decreases drastically at the boron concentration of 1×10²⁰ (cm⁻³) or more to be several tenth part of the etching rate at the boron concentration of 1×10¹⁹ (cm⁻³) or less. In the embodiment, the boron concentration in the electrode films WL1 to WL4 is, for example, 1×10²¹ (cm⁻³) to 2×10²¹ (cm⁻³).

For example, the lower layer side electrode film is caused to have a lower boron concentration. As the boron concentration becomes lower, the etching rate by the alkaline chemical becomes higher. Accordingly, in the wet etching using the above alkaline chemical, the side wall of the lower layer side electrode film facing the memory hole MH is etched and recedes in the direction apart from the center axis of the memory hole MH. That is, the hole diameter of the memory hole MH on the bottom side is increased and the taper shape of the memory hole MH on the bottom side is improved. It is possible to improve the bowing shape.

Dissolve of portions with a small hole diameter in the memory hole MH can prevent the memory hole from being blocked by the memory film formed in the later process.

For the electrode film having a lower boron concentration, etching tends to proceed also in the thickness direction. Accordingly, the electrode film having a lower boron concentration (higher layer side electrode film in the embodiment) is deposited to have a larger thickness and configured to have a desired film thickness after the above wet etching.

A boron concentration not lower than 5×10²⁰ (cm⁻³) is sufficient for the electrode films WL1 to WL4 to function as the control gates of the memory cell. The embodiment causes the concentration difference to be generated among the electrode films WL1 to WL4 in a concentration region not lower than 1×10²¹ (cm⁻³) which is further higher than the electrically sufficient concentration.

Since the boron concentration difference is caused to be generated among the electrode films WL1 to WL4 in the concentration region considerably higher than the electrically sufficient boron concentration, the boron concentration difference among the electrode films WL1 to WL4 does not lead to a difference of the memory cell characteristics among the different layers.

Due to the recession of the side wall of the electrode films WL1 to WL4 caused by the wet etching, as shown in FIG. 12B, an end 42a facing the memory hole MH in the insulating film 42 may protrude into the memory hole MH with respect to the side wall of the electrode films WL1 to WL4.

In that case, the end 42a of the insulating film 42 is etched with an etchant including hydrofluoric acid, for example, such as diluted hydrofluoric acid, BHF (Buffered Hydrogen Fluoride).

The insulating film 42 is a silicon oxide film added with, for example, boron as an impurity. The etching rate of the insulating film 42 to diluted hydrofluoric acid and BHF depends on the boron concentration doped into the insulating film 42. The etching rate of the insulating film 42 by diluted hydrofluoric acid and BHF tends to increase with increasing boron concentration.

Therefore, when wet etching using diluted hydrofluoric acid and BHF, etching of the end 42a facing the memory hole MH proceeds with increasing boron concentration in the insulating film 42, and the end 42a recesses in a direction moving away from the center axis of the memory hole MH. Thereby, portions with a locally small hole diameter in the memory hole MH are dissolved and the block by the memory film can be prevented.

As described previously, the electrode films on the lower layer side have a lower boron concentration than the electrode films on the upper layer side, and the etching amount is high. Therefore, the insulating film 42 on the lower layer side is likely to have larger protrusion amount than the insulating film 42 on the upper layer side. Thus, if the boron concentration in the insulating film 42 on the lower layer side is higher than the boron concentration in the insulating film 42 on the upper layer side, the etching rate of the insulating film 42 on the lower layer side with a larger protrusion amount can be accelerated while suppressing the etching amount of the insulating film 42 on the upper layer side.

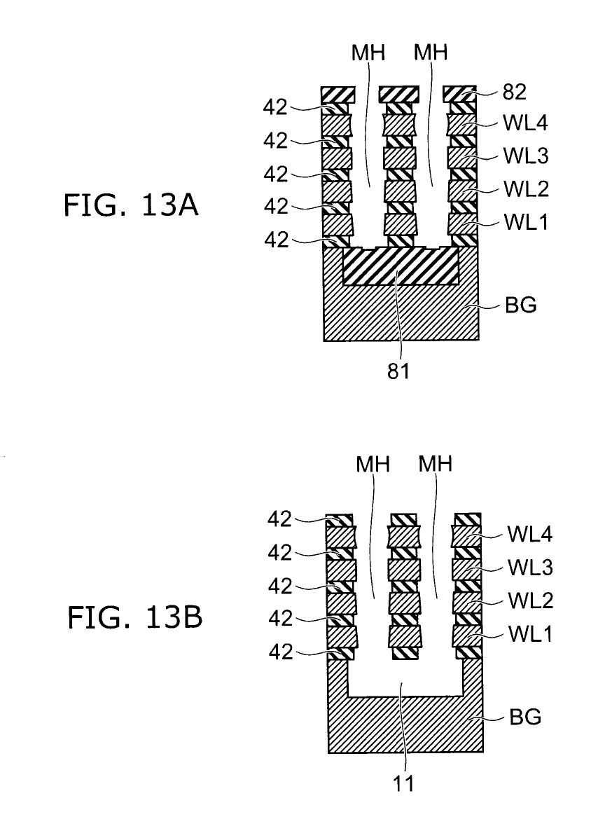

As a result, as shown in FIG. 13A, variation of the hole diameter in the depth direction of the memory hole can be reduced.

Here, the end 42a of the insulating film 42 can also be removed by the RIE method being anisotropic dry etching. FIG. 15 shows the state after the RIE.

Compared with the etching, the RIE method can suppress side etching of the insulating film 42, and prevent disappearance of the insulating film 42 between adjacent memory holes.

After processes of FIG. 13A and FIG. 15, the sacrifice film 81 is removed by etching through the memory hole MH. The trenches 11 formed on the back gate BG appear by removal of the sacrifice film 81 as shown in FIG. 13B. Bottom of each of a pair of memory holes MH communicates with one common trench 11 and one U-shaped memory hole is formed.

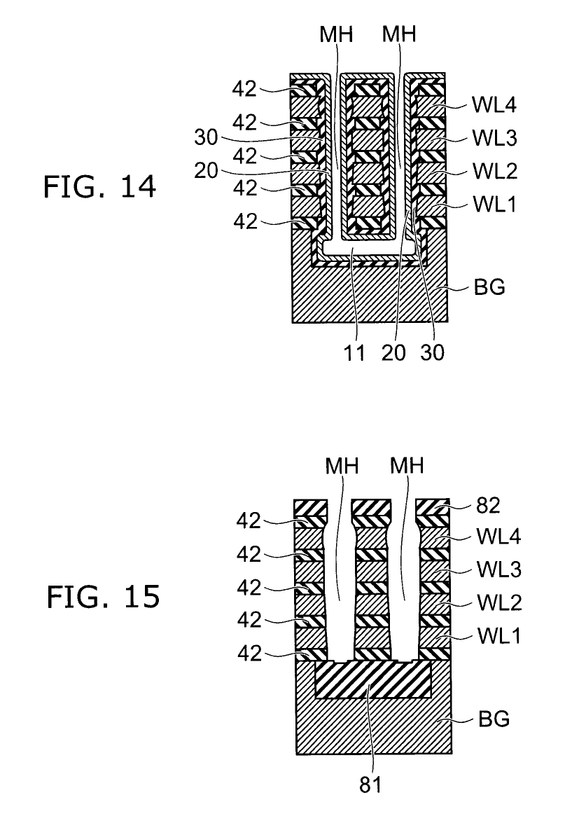

Next, as shown in FIG. 14, the memory film 30 is formed on the side wall of the memory hole MH. As described with reference to FIG. 2, the memory film 30 includes the block film 31, the charge storage film 32 and the tunnel film 33 sequentially stacked from the side wall side of the memory hole MH.

Furthermore, the channel body 20 is formed inside the memory film 30 within the memory hole MH. After that, the contact not shown, the source line SL and the bit line BL shown in FIG. 1 or the like are formed.

According to the embodiment described above, even if the shape of the memory hole MH is not processed as desired by the RIE method, the shape of the memory hole MH can be adjusted by changing the impurity concentration among different layers of the electrode films and the inter-electrode insulating films and using the etching rate difference between the films to the wet etching caused by the impurity concentration difference.

In the above embodiments, although the wet etching of the silicon film and the silicon oxide film is illustrated, similar wet etching is possible for materials that the etching rate varies greatly with the impurity concentration. The impurity added to the electrode films WL1 to WL4 and the insulating film 42 is not limited to boron, but for example, phosphorous may be used. An adequate etchant is selected in accordance with film type and added impurity type.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A manufacturing method of a semiconductor memory device, comprising:
forming a stacked body on a substrate, the stacked body including:
a plurality of first silicon films containing impurities and having a concentration difference of the impurities provided among different layers; and
a plurality of non-doped second silicon films each provided between the first silicon films;
forming a hole in the stacked body;
removing the second silicon films by etching through the hole and forming an inter-electrode space between the first silicon films;
forming a memory film including a charge storage film on a side wall of the hole and also forming at least a part of the memory film in the inter-electrode space; and
forming a channel body inside the memory film within the hole.

2. The method according to claim 1, wherein
the plurality of first silicon films are provided with a concentration difference of the impurities in a concentration region not lower than 1×10²¹ (cm⁻³).

3. The method according to claim 1, wherein
an impurity concentration of the first silicon films on a lower layer side is lower than an impurity concentration of the first silicon films on an upper layer side.

4. The method according to claim 1, wherein
the impurities are boron.

5. The method according to claim 1, wherein
the second silicon films are removed with alkaline chemical.

6. A manufacturing method of a semiconductor memory device, comprising:
forming a stacked body on a substrate, the stacked body including:
a plurality of electrode films containing impurities and having a concentration difference of the impurities provided among different layers; and
a plurality of insulating films each provided between the electrode films;
forming a hole in the stacked body;
etching a side wall of the electrode films exposed to the hole with an etchant;
forming a memory film including a charge storage film on a side wall of the hole; and
forming a channel body inside the memory film within the hole,
an etching rate of the electrode films to the etchant depending on a concentration of the impurities contained in the electrode films.

7. The method according to claim 6, further comprising
after the etching the electrode films and before the forming the memory film, removing an end of the insulating film protruding into the hole with respect to the electrode films.

8. The method according to claim 7, wherein
the end of the insulating film is removed by wet etching.

9. The method according to claim 8, wherein
the insulating film contains impurities, and
an etching rate of the insulating film to the wet etching depends on a concentration of the impurities contained in the insulating films.

10. The method according to claim 9, wherein
the insulating film contains boron as the impurities.

11. The method according to claim 10, wherein
the insulating film is etched using an etchant containing hydrofluoric acid.

12. The method according to claim 7, wherein
the end of the insulating film is removed by anisotrpic dry etching.

13. The method according to claim 6, wherein
the electrode films are silicon films, and
the silicon films are provided with the concentration difference of the impurities in a concentration region not lower than 1×10²¹ (cm⁻³).

14. The method according to claim 6, wherein
the impurities are boron.

15. The method according to claim 6, wherein
an impurity concentration of the electrode films on a lower layer side is lower than an impurity concentration of the electrode films on an upper layer side.

16. A semiconductor memory device, comprising:
a substrate;
a stacked body including a plurality of electrode films and a plurality of insulating films, both of them being stacked alternately on the substrate;
a channel body provided in a hole formed passing through the stacked body; and
a memory film provided between a side wall of the hole and the channel body and including a charge storage film,
the plurality of electrode films including a plurality of silicon films, the silicon films containing impurities and having a concentration difference of the impurities provided among different layers.

17. The device according to claim 16, wherein
the electrode films are provided with the concentration difference of the impurities in a concentration region not lower than 1×10²¹ (cm⁻³).

18. The device according to claim 16, wherein
an impurity concentration of the electrode films on a lower layer side is lower than an impurity concentration of the electrode films on an upper layer side.

19. The device according to claim 16, wherein
the electrode films are a silicon films containing boron as the impurities.

20. The device according to claim 16, wherein
the insulating film contains impurities and having a concentration difference of the impurities provided among different layers.
